(19) United States
(12) Patent Application Publication
(10) Pub. No.: US 2012/0326147 A1
(43) Pub. Date: Dec. 27, 2012

(54) SEMICONDUCTOR CHIP, METHOD OF MANUFACTURING THE SAME, AND SEMICONDUCTOR PACKAGE

(75) Inventor: Naoto AKIYAMA, Kanagawa (JP)

(73) Assignee: RENESAS ELECTRONICS CORPORATION, Kanagawa (JP)

(21) Appl. No.: 13/479,927

(22) Filed: May 24, 2012

(30) Foreign Application Priority Data
Jun. 22, 2011 (JP) 2011-138711

(51) Int. Cl. H01L 23/48; H01L 21/66

(52) U.S. Cl. 257/48; 438/18; 257/E23.01; 257/E21.521

(57) ABSTRACT

Provided is a semiconductor chip in which a first rewiring connection part located in the peripheral electrode pad or relatively close to the peripheral electrode pad in the V/G line and a second rewiring connection part located relatively distant from the peripheral electrode pad in the V/G line and having a lower potential than the first rewiring connection part before formation of a rewiring line are connected by the rewiring line. The semiconductor chip includes an inspection part for wafer test in the second rewiring connection part, a part on the V/G line close to the second rewiring connection part and having a lower potential than the first rewiring connection part before the rewiring line formation, or a conductive part extended from the V/G line to a proximity of the second rewiring connection part and having a lower potential than the first rewiring connection part before the rewiring line formation.

### CROSS-REFERENCE TO RELATED APPLICATIONS

This application is based upon and claims the benefit of priority from Japanese patent application No. 2011-138711, filed on Jun. 22, 2011, the disclosure of which is incorporated herein in its entirety by reference.

### BACKGROUND

The present invention relates to a semiconductor chip, a method of manufacturing the same, and a semiconductor package using the semiconductor chip.

A plurality of semiconductor chips are manufactured at once by forming a plurality of semiconductor chips all together on a single semiconductor wafer and dividing them. One or a plurality of semiconductor chips are mounted onto a package substrate, for example, thereby manufacturing a finished semiconductor product such as a semiconductor package.

In the manufacture of a semiconductor chip and the manufacture of a finished semiconductor product using the semiconductor chip, an operation check is performed.

Generally, in the manufacture of a semiconductor chip, at the point when top-layer lines including a plurality of V/G lines serving as a power supply (V) line or a ground (G) line and a plurality of peripheral electrode pads formed in a peripheral area where an internal circuit is not formed and connected to the V/G lines are formed, a wafer test (WT) that performs an operation check of the internal circuit is conducted by bringing a probe into contact with the peripheral electrode pads.

FIG. 6A is a cross-sectional view of a main part of a semiconductor chip according to related art, and FIG. 6B is a plan view of the same main part. It is assumed that steps of an electrode pad or the like in the figures are one example, and the steps depend on a lower-layer structure.

In the figures, the reference symbol W indicates a wafer and lower-layer lines, 210 indicates an insulating film, 220 indicates a V/G line, 230 indicates a peripheral electrode pad, 250 indicates an insulating film, and 270 indicates a protective film. The reference symbol E in the plan view indicates the edge of the semiconductor chip.

In the semiconductor chip, a potential drop (IR drop) that a potential supplied from the peripheral electrode pad 230 significantly drops in a part 220D of the V/G line 220 which is away from the peripheral electrode pad 230 occurs in some cases depending on the impedance of the V/G line.

To reduce the potential drop, a structure in which the peripheral electrode pad 230 and a part of the V/G line 220 where a large potential drop occurs are connected like a bridge by a rewiring line 260 as shown in FIGS. 7A and 7B to equalize the potentials of the peripheral electrode pad 230 and the part of the V/G line 220 where a large potential drop occurs may be used.

In the figures, the reference symbol 261 indicates a rewiring connection part in the peripheral electrode pad 230, and the reference symbol 262 indicates a rewiring connection part in the V/G line 220.

In the rewiring structure shown in FIGS. 7A and 7B, the above-described wafer test is often conducted after the top-layer lines including the V/G line 220 and the peripheral electrode pad 230 are formed and before the rewiring line 260 is formed. One reason is that a production line or a manufacturing facility for the formation of the rewiring line 260 is different from that for the previous processes.

However, a case can occur where a potential drop occurs in the rewiring connection part 262 of the V/G line 220, which is supposed to have the same potential as the peripheral electrode pad 230 after formation of the rewiring line 260, during the wafer test before formation of the rewiring line 260, and, as a result, the semiconductor chip that is non-defective in the final test (FT) in the form of a finished product is determined to be defective in the wafer test before formation of the rewiring line 260. Specifically, because the impedance of the V/G line 220 changes before and after formation of the rewiring line 260, non-defective/defective determination is not accurately made in the wafer test before formation of the rewiring line 260.

A structure in which a second power supply pad to be used only for probe testing, in addition to a first power supply pad to be used also for a final product, is provided to reduce power supply impedance during probe testing is disclosed in Japanese Unexamined Patent Application Publication No. H08-227921 (which is referred to hereinafter as Patent Literature 1) (see Claim 1 and FIGS. 2 and 3 of Patent Literature 1).

Patent Literature 1 contains description that “during probe testing, a plurality of probes are connected in parallel between a power supply and first and second power supply pads. The DC resistances of the probes obtained as the sum of the resistance of the probe and the contact resistance between the probe and the power supply pad are thereby connected in parallel, resulting in a decrease in the DC resistances. Further, because a plurality of probes are tightly packed, self-inductance is reduced. This results in a decrease in power supply impedance during probe testing” (see Paragraph 0031 of Patent Literature 1).

### SUMMARY

Patent Literature 1 contains no disclosure about the rewiring structure shown in FIGS. 7A and 7B. Therefore, Patent Literature 1 discloses nothing about a problem that determination in probe testing is not accurately made due to a change in the impedance of the V/G line before and after formation of the rewiring line and a solution to the problem.

A first aspect of the present invention is a semiconductor chip that includes a V/G line formed by top-layer lines of the semiconductor chip and serving as a power supply (V) line or a ground (G) line connected to an internal circuit, and a peripheral electrode pad formed in a peripheral area where the internal circuit is not formed and connected to the V/G line, in which a first rewiring connection part located in the peripheral electrode pad or at a relatively close position to the peripheral electrode pad in the V/G line and a second rewiring connection part located at a relatively distant position from the peripheral electrode pad in the V/G line and having a lower potential than the first rewiring connection part before formation of a rewiring line are connected by the rewiring line, and an inspection part to come into contact with a wafer test probe before formation of the rewiring line is placed in the second rewiring connection part, a part on the V/G line in close proximity to the second rewiring connection part and having a lower potential than the first rewiring connection part before formation of the rewiring line, or a conductive part extended from the V/G line to a proximity of the second rewiring connection part and having a lower potential than the first rewiring connection part before formation of the rewiring line.

A second aspect of the present invention is a method of manufacturing a semiconductor chip that includes a step (1) of forming the top-layer lines including the V/G line, the peripheral electrode pad, and the inspection part (the inspection part is included in the V/G line in some cases), a step (2) of inspecting operations of the semiconductor chip by bringing a probe into contact with at least the inspection part of the peripheral electrode pad and the inspection part, and a step (3) of forming the rewiring line.

In the semiconductor chip of the aspect of the present invention, the inspection part for a wafer test before formation of the rewiring line is placed in the second rewiring connection part or its proximity in which a potential drop occurs before formation of the rewiring line and which has the same potential as the peripheral electrode pad after formation of the rewiring line. In this structure, the effect of the potential drop of the V/G line before formation of the rewiring line is reduced, and the wafer test before formation of the rewiring line can be performed under the same or similar conditions as those after formation of the rewiring line. The accuracy of non-defective/defective determination in the wafer test before formation of the rewiring line is thereby improved, so that the wafer test before formation of the rewiring line can be conducted properly.

According to the aspect of the present invention, it is possible to provide the semiconductor chip having the rewiring structure to reduce the potential drop of the V/G line and capable of appropriately conducting the wafer test before formation of the rewiring line, and a method of manufacturing the same.

### BRIEF DESCRIPTION OF THE DRAWINGS

The above and other aspects, advantages and features will be more apparent from the following description of certain embodiments taken in conjunction with the accompanying drawings, in which:

FIG. 1A is a cross-sectional view of a main part of a semiconductor chip according to one embodiment of the invention before formation of a rewiring line;

FIG. 1B is a cross-sectional view of a main part of a semiconductor chip according to one embodiment of the invention after formation of a rewiring line;

FIG. 1C is a cross-sectional view of a main part of a semiconductor package using the semiconductor chip of FIG. 1B;

FIG. 2A is a plan view of a main part of the semiconductor chip of FIG. 1A (during wafer test);

FIG. 2B is a plan view of a main part of the semiconductor chip of FIG. 1B in which an external connection terminal is formed on a peripheral electrode pad (during final test);

FIG. 3A is a cross-sectional view of a main part showing an example of design change of a semiconductor chip according to one embodiment of the invention;

FIG. 3B is a cross-sectional view of a main part of a semiconductor package using the semiconductor chip of FIG. 3A;

FIG. 4A is a plan view of a main part showing an example of design change of a semiconductor chip according to one embodiment of the invention;

FIG. 4B is a plan view of a main part showing an example of design change of a semiconductor chip according to one embodiment of the invention;

FIG. 4C is a plan view of a main part showing an example of design change of a semiconductor chip according to one embodiment of the invention;

FIG. 5 is a plan view of a main part showing an example of design change of a semiconductor chip according to one embodiment of the invention;

FIG. 6A is a cross-sectional view of a main part of a semiconductor chip according to related art;

FIG. 6B is a plan view of a main part of the semiconductor chip in FIG. 6A;

FIG. 7A is a cross-sectional view of a main part of another semiconductor chip according to related art; and

FIG. 7B is a plan view of a main part of the semiconductor chip in FIG. 7A.

### DETAILED DESCRIPTION

A structure of a semiconductor chip according to one embodiment of the present invention, a method of manufacturing the same, and a semiconductor package using the semiconductor chip are described hereinafter with reference to the drawings.

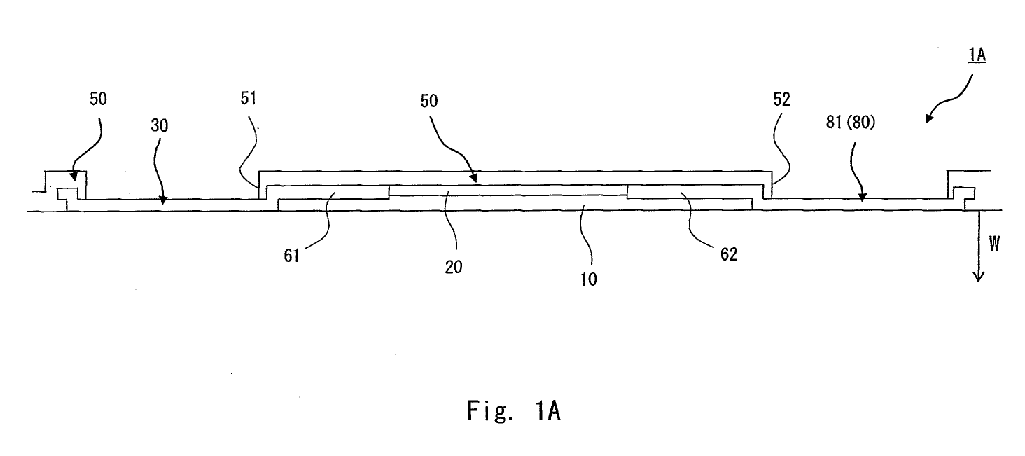

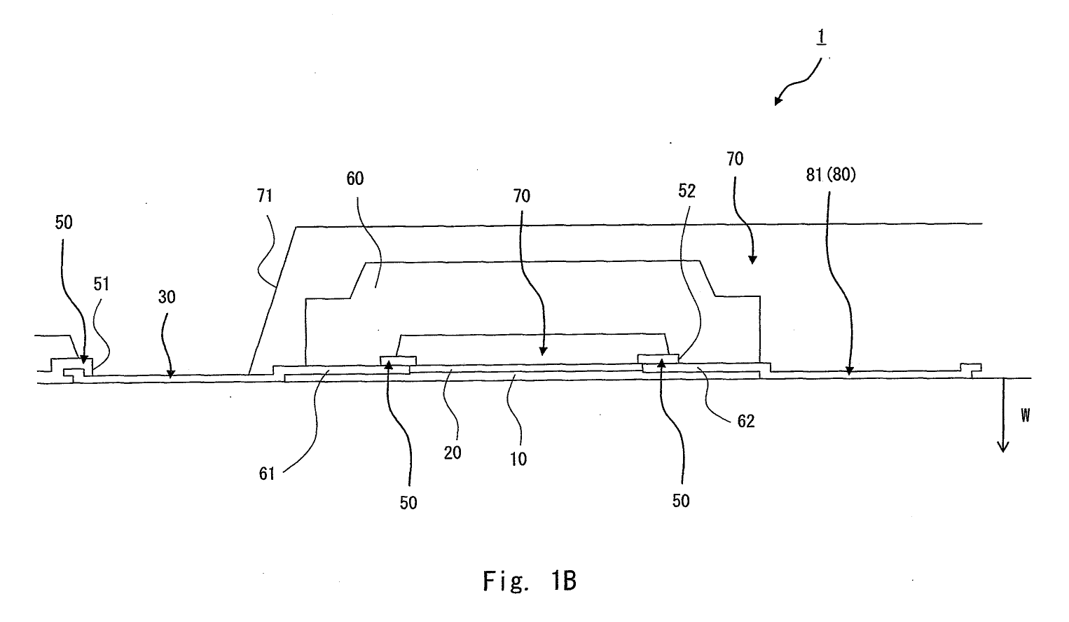

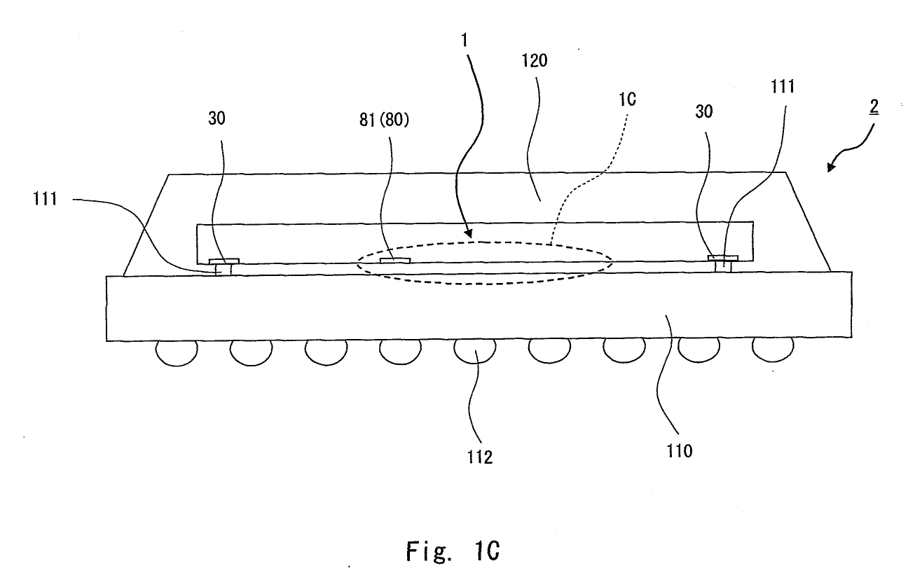

FIG. 1A is a cross-sectional view of a main part of a semiconductor chip according to the embodiment before formation of a rewiring line. FIG. 1B is a cross-sectional view of a main part of a semiconductor chip according to the embodiment after formation of a rewiring line. FIG. 1C is a cross-sectional view of a main part of a semiconductor package using the semiconductor chip of FIG. 1B. In FIGS. 1A and 1B, it is assumed that steps of an electrode pad or the like in the figures are one example, and the steps depend on a lower-layer structure. Further, an IO element is typically connected between a peripheral electrode pad 30 and a V/G line 20, though not shown.

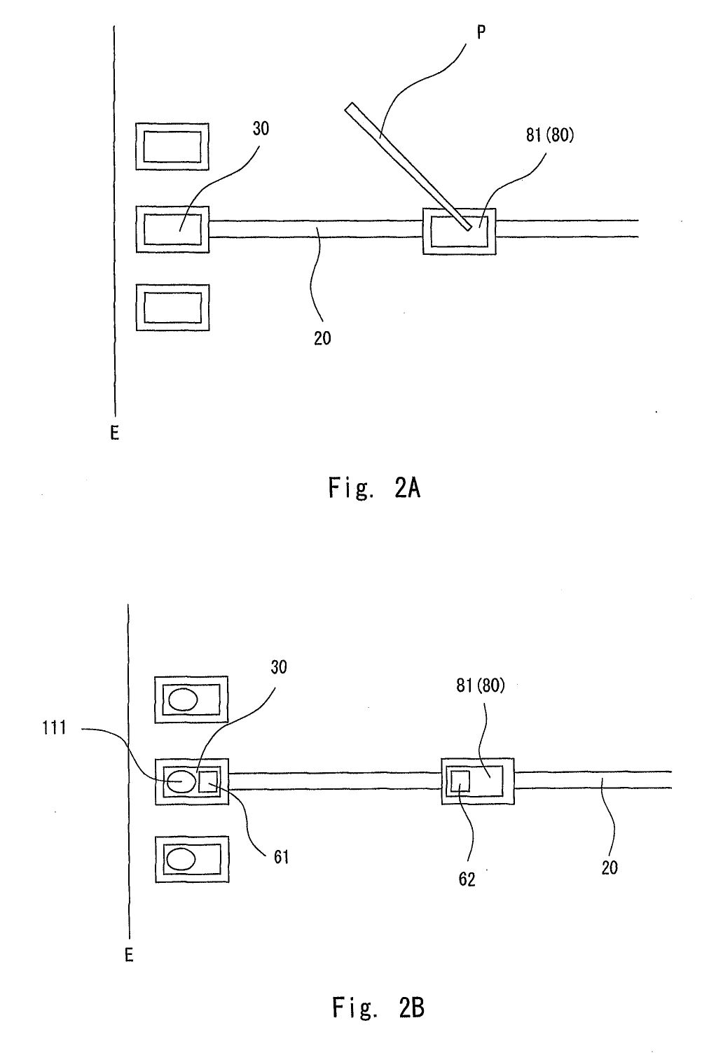

FIG. 2A is a plan view of a main part of the semiconductor chip of FIG. 1A (during wafer test). FIG. 2B is a plan view of a main part of the semiconductor chip of FIG. 1B in which an external connection terminal is formed on a peripheral electrode pad (during final test).

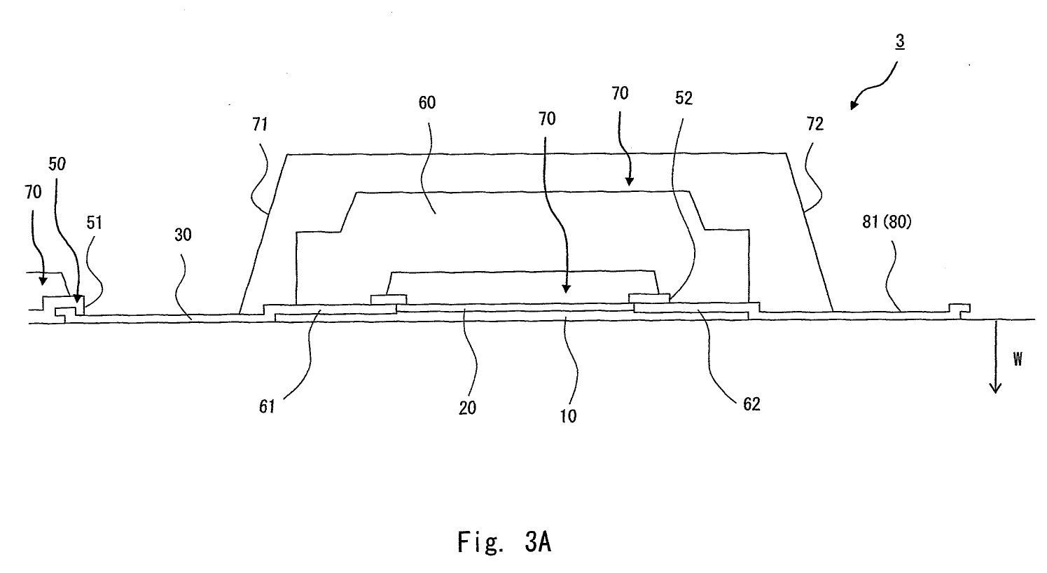

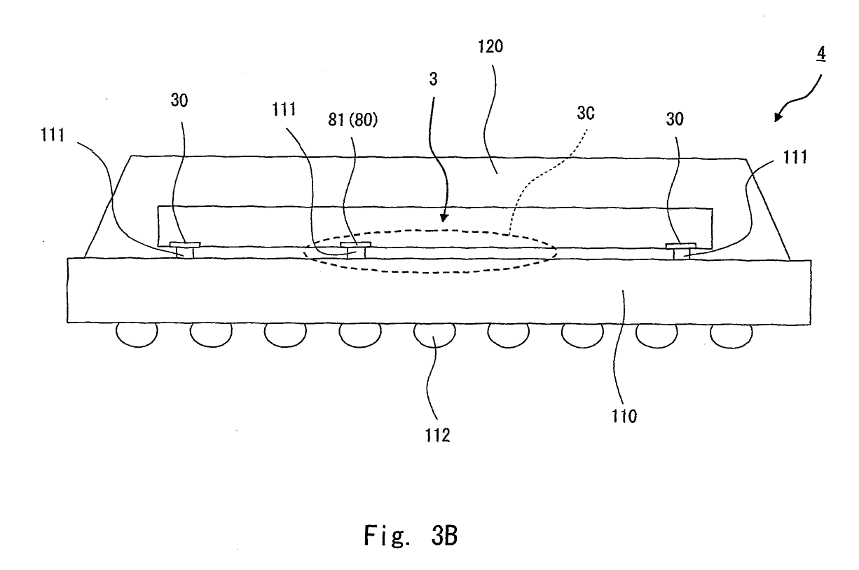

FIGS. 3A to 3B, FIGS. 4A to 4C and FIG. 5 are views showing examples of design changes.

Those figures are schematic views and given in simplified form, different from the actual form as appropriate.

In the figures, the reference symbol 1A indicates a semiconductor chip before forming a rewiring line, and 1 indicates a semiconductor chip after forming a rewiring line.

The reference symbol W indicates a wafer and lower-layer lines, 10 indicates an insulating film, 20 indicates a V/G line, 30 indicates a peripheral electrode pad, 50 indicates an insulating film, 60 indicates a rewiring line, 70 indicates a protective film, and 110 indicates a package substrate. The reference symbol P indicates an inspection probe.

The reference symbol E in the plan view indicates the edge of the semiconductor chip.

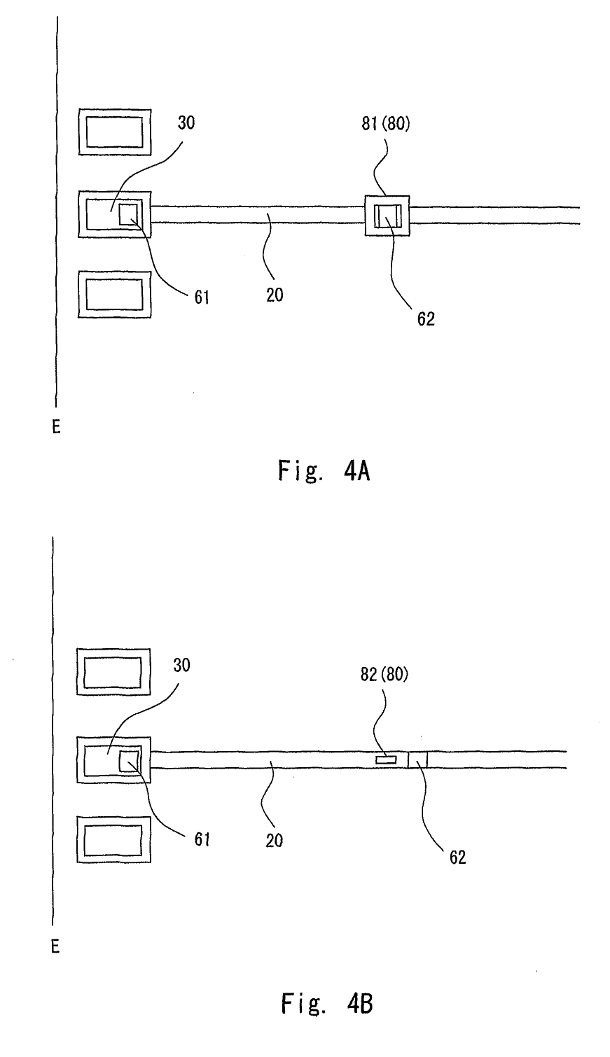

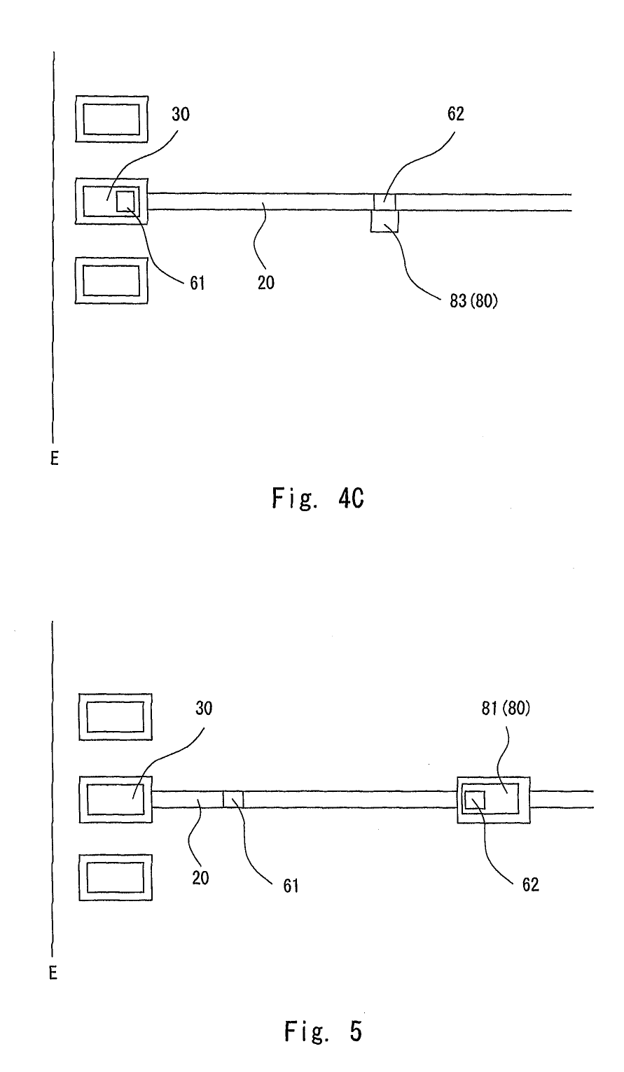

In FIGS. 2A, 2B and 4A, in a double square indicating the peripheral electrode pad 30 and an inspection electrode pad 81 (inspection part 80), the outer square indicates the edge of the electrode pad, and the inner square indicates the opening of the insulating film 50 in the upper layer of the electrode pad.

In FIG. 4B, the square indicating an inspection part 82 is shown by the opening of the insulating film 50 in its upper layer.

As shown in FIG. 1B and the like, the semiconductor chip 1 according to this embodiment is a LSI (Large Scale integration) chip that includes a plurality of V/G lines 20 formed as the top-layer lines of the semiconductor chip 1 and to serve as a power supply (V) line or a ground (G) line connected to an internal circuit, and a plurality of peripheral electrode pads 30 formed in a peripheral area where the internal circuit is not formed and connected to the V/G lines 20.

The top-layer lines, the insulating film 50 in the upper layer of the peripheral electrode pad 30, and the protective film 70 in the outermost surface of the semiconductor chip 1 have an opening 51 and an opening 71, respectively, just above the peripheral electrode pad 30.

As described in the above “BACKGROUND”, in the semiconductor chip, a potential drop (IR drop) that a potential supplied from the peripheral electrode pad significantly drops in a part of the V/G line which is away from the peripheral electrode pad occurs in some cases depending on the impedance of the V/G line.

In this embodiment, to reduce the potential drop, a first rewiring connection part 61 that is located in the peripheral electrode pad 30 or at a relatively close position to the peripheral electrode pad 30 in the V/G line 20 and a second rewiring connection part 62 that is located at a relatively distant position from the peripheral electrode pad 30 in the V/G line 20 and has a lower potential than the first rewiring connection part 61 before formation of the rewiring line 60 are connected like a bridge by the rewiring line 60.

In the example shown in FIGS. 1A and 1B, the opening 51 of the insulating film 50 is enlarged after formation of the rewiring line 60 compared to before formation of the rewiring line 60. The first rewiring connection part 61 is provided in the enlarged area of the opening 51, and the first rewiring connection part 61 is formed inside the peripheral electrode pad 30. In this structure, because the positions of the peripheral electrode pad 30 and the first rewiring connection part 61 coincide, the potential of the first rewiring connection part 61 before formation of the rewiring line 60 is the same as the potential of the peripheral electrode pad 30 by necessity.

As shown in FIG. 5, the first rewiring connection part 61 may be placed at a relatively close position to the peripheral electrode pad 30 in the V/G line 20. In this case, the potential of the first rewiring connection part 61 before formation of the rewiring line 60 may be slightly different from the potential of the peripheral electrode pad 30 and, preferably, is the same potential.

The second rewiring connection part 62 is located in a region where a significant potential drop occurs before formation of the rewiring line 60 and in a region where the potential drop of the V/G line 20 is sufficiently reduced after formation of the rewiring line 60.

The part where the potential drop of the V/G line 20 is large before formation of the rewiring line 60 is a part where the internal circuits are tightly packed or a part where a high-speed signal is transmitted, and it is typically a center part where the internal circuit of the semiconductor chip is formed. In FIGS. 1C and 3B, the regions where the potential drop of the V/G line 20 is large before formation of the rewiring line 60 in the semiconductor chip 1, 3 are schematically shown by the reference symbols 1C and 3C, respectively. The part where the potential drop of the V/G line 20 is large before formation of the rewiring line 60 can be specified by simulation.

The level of reducing the potential drop in the V/G line 20 after formation of the rewiring line compared with that before formation of the rewiring line can be represented by impedance between the first rewiring connection part 61 and the second rewiring connection part 62.

Specifically, the impedance between the first rewiring connection part 61 and the second rewiring connection part 62 after formation of the rewiring line 60 is preferably ½ or less of that before formation of the rewiring line 60, preferably ⅕ or less, and more preferably 1/10 or less.

In this embodiment, the inspection part 80 to come into contact with an inspection probe before formation of the rewiring line 60 is provided in the second rewiring connection part 62, a part on the V/G line 20 in close proximity to the second rewiring connection part 62 and having a lower potential than the first rewiring connection part 61 before formation of the rewiring line 60, or a conductive part extended from the V/G line 20 to the proximity of the second rewiring connection part 62 and having a lower potential than the first rewiring connection part 61 before formation of the rewiring line 60.

In the example shown in FIG. 1B, the inspection electrode pad 81 is provided as the inspection part 80.

The insulating film 50 has an opening 52 just above the inspection electrode pad 81, so that the surface of the inspection electrode pad 81 is exposed at least before formation of the rewiring line 60 as shown in FIG. 1A.

In the example shown in FIGS. 1A and 1B, the opening 52 of the insulating film 50 is enlarged after formation of the rewiring line 60 compared to before formation of the rewiring line 60. The second rewiring connection part 62 is provided in the enlarged area of the opening 52, and the second rewiring connection part 62 is formed inside the inspection electrode pad 81. In this structure, because the positions of the second rewiring connection part 62 and the inspection electrode pad 81 coincide, the potential of the inspection electrode pad 81 (the inspection part 80) before formation of the rewiring line 60 is the same as the potential of the second rewiring connection part 62 by necessity.

The inspection electrode pad 81 (the inspection part 80) may be provided in close proximity to the second rewiring connection part 62. In this case, the potential of the inspection electrode pad 81 (the inspection part 80) before formation of the rewiring line 60 may be slightly different from the potential of the second rewiring connection part 62 and, preferably, is the same potential.

The inspection electrode pad 81 may be connected to a package substrate and used as an electrode pad in a final product or may not be connected to a package substrate and used for inspection only.

In the example shown in FIG. 1B, the inspection electrode pad 81 is an electrode pad that is not connected to a package substrate and used for inspection only. Thus, the protective film 70 does not have an opening just above the inspection electrode pad 81.

A semiconductor package 2 shown in FIG. 1C is a package in which the peripheral electrode pad 30 of the semiconductor chip 1 and the package substrate 110 are connected by external connection terminals 111 such as bumps or pillars and sealed by a sealing resin 120. External connection terminals 112 such as BGA balls are formed on the backside of the package substrate 110.

In this example, the external connection terminals 111 such as bumps or pillars are not formed on the inspection electrode pad 81, the package substrate 110 does not have lands for the inspection electrode pad 81, and the inspection electrode pad 81 and the package substrate 110 are not connected.

FIG. 1C shows just an example of a flip-chip (FC) package, and the semiconductor chip 1 may be mounted onto the package substrate 110 in arbitrary ways.

In a semiconductor chip 3 shown in FIG. 3A, the inspection electrode pad 81 is connected to the package substrate 110 and used as an electrode pad in a final product. In this semiconductor chip 3, the protective film 70 has an opening 72 just above the inspection electrode pad 81. As shown in FIG. 3B, in a semiconductor package 4 using the semiconductor chip 3, the external connection terminals 111 such as bumps or pillars are formed on the inspection electrode pad 81, the package substrate 110 has lands for the inspection electrode pad 81, and the inspection electrode pad 81 and the package substrate 110 are connected.

In the case of connecting the inspection electrode pad 81 and the package substrate 110, advantages such as stable LSI operation are obtained. This is because the layout flexibility of the package substrate increases, and impedance between an external VG terminal of the package and the V/G line inside the LSI can be reduced with a shorter connection distance or easier connection between the external VG terminal of the package and the V/G line inside the LSI.

The size of the inspection electrode pad 81 is not particularly limited, and it may be substantially the same as the size of the peripheral electrode pad 30 as shown in FIG. 2A, or may be smaller than the size of the peripheral electrode pad 30.

As shown in FIG. 4B, the inspection part 80 may be a part 82 of the V/G line 20. Although the case where the inspection part 80 is provided in close proximity to the second rewiring connection part 62 is illustrated in FIG. 4B, the positions of the inspection part 80 and the second rewiring connection part 62 may coincide.

As shown in FIG. 4C, the inspection part 80 may be a conductive part 83 that is formed in close proximity to the second rewiring connection part 62 and extended from the V/G line 20.

In the structure shown in FIGS. 4B and 4C, the dedicated area of the inspection part 80 can be small, thus preventing the degree of integration of the semiconductor chip 1 from decreasing due to formation of the inspection part 80.

In any examples, an open area of the opening 52 of the insulating film 50 in the upper layer of the inspection part 80 is a region to come into contact with the probe P, which is an effective inspection area.

A method of manufacturing the semiconductor chip 1 according to this embodiment is described hereinbelow.

### <Step (1)>

On the wafer W in which the lower-layer lines are formed, the top-layer lines including the V/G line 20, the peripheral electrode pad 30 and the inspection electrode pad 81 are formed by a known method.

Further, the insulating film 50 is formed thereon by a known method, and the openings 51 and 52 are created in the insulating film 50 just above the peripheral electrode pad 30 and the inspection electrode pad 81, respectively.

### <Step (2)>

Next, the inspection probe P is brought into contact with at least the inspection electrode pad 81 of the peripheral electrode pad 30 and the inspection electrode pad 81 as shown in FIG. 2A to provide a power supply to the internal circuit and detect a signal from a signal pad (not shown), thereby conducting a wafer test (WT) to inspect operations of the semiconductor chip 1.

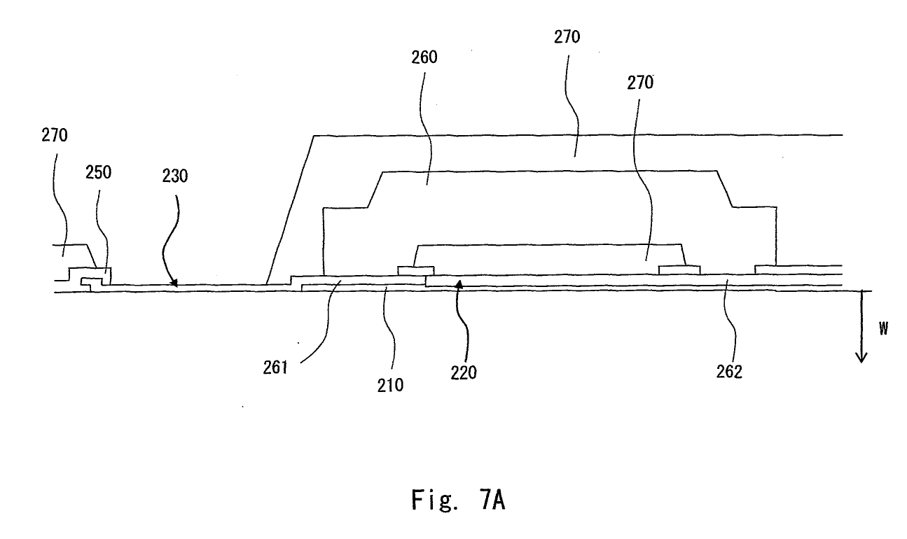

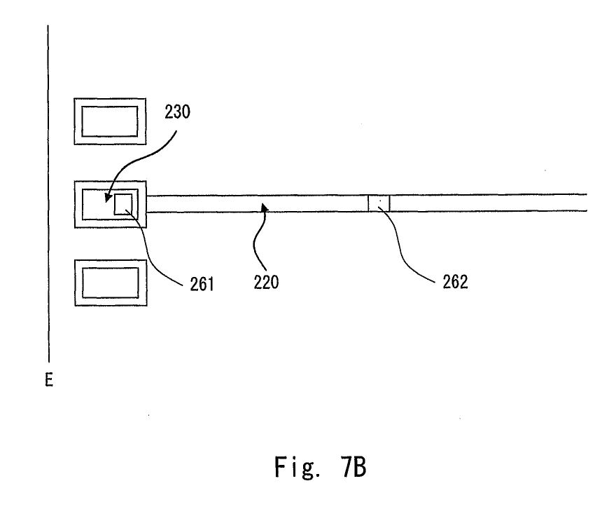

In the existing structure shown n FIGS. 7A and 7B with no inspection electrode pad, when performing a wafer test before formation of a rewiring line by bringing a probe into contact with the inspection electrode pad, the potential of the second rewiring connection part during the wafer test is significantly lower than that after formation of a rewiring line, and the wafer test cannot be conducted under the conditions of a final product.

On the other hand, in this embodiment, because the potential of the first rewiring connection part 61 and the potential of the second rewiring connection part 62 are equalized after formation of the rewiring line 60, the potential of the peripheral electrode pad 30 where the first rewiring connection part 61 exists and the potential of the inspection electrode pad 81 where the second rewiring connection part 62 exists are equalized after formation of the rewiring line 60.

By bringing the probe P into contact with the inspection electrode pad 81 before formation of the rewiring line 60, the potential of the inspection electrode pad 81 before formation of the rewiring line 60 can coincide with the potential of the peripheral electrode pad 30 and the inspection electrode pad 81 after formation of the rewiring line 60, thereby allowing the wafer test to be conducted under the conditions of a final product. This enables correct non-defective/defective determination in the wafer test.

The position of the second rewiring connection part 62 is preferably a position where the potential drop of the V/G line 20 is large before formation of the rewiring line 60.

As is already described above, the part where the potential drop of the V/G line 20 is large before formation of the rewiring line 60 is a part where the internal circuits are tightly packed or a part where a high-speed signal is transmitted, and it is typically a center part of the area where the internal circuit of the semiconductor chip is formed (see the areas indicated by the reference symbol 1C in FIGS. 1C and 3C in FIG. 3B). The part where the potential drop of the V/G line 20 is large before formation of the rewiring line 60 can be specified by simulation.

It is particularly preferred that the potential of the first rewiring connection part 61 before formation of the rewiring line 60 is the same as the potential of the peripheral electrode pad 30, and the potential of the inspection electrode pad 81 before formation of the rewiring line 60 is the same as the potential of the second rewiring connection part 62, and the first rewiring connection part 61 and the inspection electrode pad 81 (the inspection part 82) are preferably placed in such positions.

However, it causes no problem when the potential of the first rewiring connection part 61 before formation of the rewiring line 60 is slightly different from the potential of the peripheral electrode pad 30, and the potential of the inspection electrode pad 81 before formation of the rewiring line 60 is slightly different from the potential of the second rewiring connection part 62. In this structure also, the conditions of a wafer test before formation of the rewiring line 60 can be close to the conditions of a final test, thus improving the accuracy of non-defective/defective determination.

In this embodiment, operations of the semiconductor chip 1 can be tested by bringing the probe P into contact with the inspection electrode pad 81 only.

In this case, a trace of the probe does not appear on the peripheral electrode pad 30, and a trace of the probe appears only on the inspection electrode pad 81. This prevents a scratch due to probing on the surface of the peripheral electrode pad 30 that is connected to the package substrate 110, which is preferable. Further, the size of the peripheral electrode pad 30 can be made smaller than before.

### <Step (3)>

After conducting the above-described wafer test, the rewiring line 60 and the protective film 70 are formed by a known method, and the openings 71 and 72 are created in the protective film 70, thereby manufacturing the semiconductor chip 1.

### <Final Test>

The semiconductor chip 1 manufactured in the above manner is mounted onto the package substrate 110 by a known method to thereby manufacture the semiconductor package 2.

The manufactured semiconductor package 2 is plugged into a test socket, and the external connection terminal 112 of the package substrate 110 and the terminal of the inspection socket are connected to conduct a final test (FT). FIG. 2B is a plan view of a main part of the semiconductor chip 1 during the final test.

Refer to FIG. 1 of Patent Literature 1 which is descried in the above “BACKGROUND” for a flowchart of a typical inspection in the semiconductor chip and the final semiconductor product.

Major differences between Patent Literature 1 descried in the above “BACKGROUND” and the present invention are described hereinafter.

Patent Literature 1 contains no disclosure about the rewiring structure that reduces the potential drop of the V/G line.

In Patent Literature 1, the second power supply pad (104, 105) is formed on the slightly inner side of a peripheral area where no internal circuit is formed in the first embodiment (FIG. 3 in Patent Literature 1), and the second power supply pad (104, 105) is formed in a scribe area in the second embodiment (FIG. 7 in Patent Literature 1). In Patent Literature 1, the place to form the second power supply pad (104, 105) is arbitrary (Paragraph 0042 in Patent Literature 1), and there is no disclosure about forming the second power supply pad in a part with a large potential drop such as at the center of the chip.

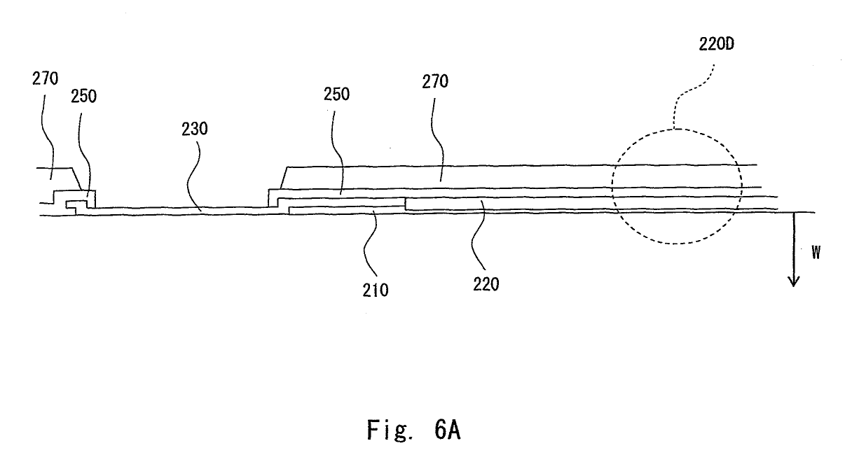

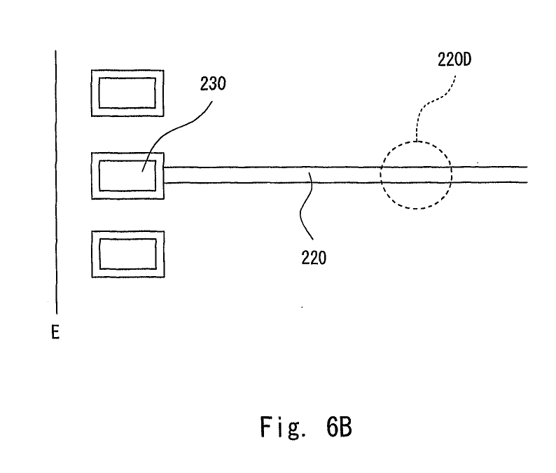

In the structure of Patent Literature 1, as shown in FIGS. 2, 3, 6 and the like thereof, it is essential to conduct a wafer test by bringing a probe into contact with the first power supply pad and the second power supply pad at the same time. In this embodiment, on the other hand, a probe may be brought into contact with the inspection part 80 only.

Note that the “rewiring line” in the embodiment of the invention is provided to reduce the potential drop of the V/G line before completion of the semiconductor chip, and it is different from a rewiring line that connects an assembly pad and a BGA ball or the like after completion of the semiconductor chip in WLP (Wafer Level Package), MCM (Multi-Chip Package) and the like.

As described above, according to the embodiment, it is possible to provide the semiconductor chip having the rewiring structure to reduce the potential drop of the V/G line and capable of appropriately conducting the wafer test before formation of the rewiring line 60, and a method of manufacturing the same.

### Design Change

While the invention has been described in terms of several embodiments, those skilled in the art will recognize that the invention can be practiced with various modifications within the spirit and scope of the appended claims and the invention is not limited to the examples described above.

Further, the scope of the claims is not limited by the embodiments described above.

Furthermore, it is noted that, Applicant's intent is to encompass equivalents of all claim elements, even if amended later during prosecution.

What is claimed is:

1. A semiconductor chip comprising:
a V/G line formed by top-layer lines of the semiconductor chip and serving as a power supply (V) line or a ground (G) line connected to an internal circuit; and
a peripheral electrode pad formed in a peripheral area where the internal circuit is not formed and connected to the V/G line, wherein
a first rewiring connection part located in the peripheral electrode pad or at a relatively close position to the peripheral electrode pad in the V/G line and a second rewiring connection part located at a relatively distant position from the peripheral electrode pad in the V/G line and having a lower potential than the first rewiring connection part before formation of a rewiring line are connected by the rewiring line, and
an inspection part to come into contact with a wafer test probe before formation of the rewiring line is placed in the second rewiring connection part, a part on the V/G line in close proximity to the second rewiring connection part and having a lower potential than the first rewiring connection part before formation of the rewiring line, or a conductive part extended from the V/G line to a proximity of the second rewiring connection part and having a lower potential than the first rewiring connection part before formation of the rewiring line.

2. The semiconductor chip according to claim 1, wherein
a potential of the first rewiring connection part before formation of the rewiring line is equal to a potential of the peripheral electrode pad, and
a potential of the inspection part before formation of the rewiring line is equal to a potential of the second rewiring connection part.

3. The semiconductor chip according to claim 1, wherein impedance between the first rewiring connection part and the second rewiring connection part after formation of the rewiring line is ½ or less of that before formation of the rewiring line.

4. The semiconductor chip according to claim 1, wherein a trace of the probe does not appear on the peripheral electrode pad, and a trace of the probe appears on the inspection part.

5. The semiconductor chip according to claim 1, wherein the inspection part is an electrode pad.

6. The semiconductor chip according to claim 1, wherein the inspection part is a part of the V/G line or the conductive part extended from the V/G line.

7. A method of manufacturing the semiconductor chip according to claim 1, comprising:
a step (1) of forming the top-layer lines including the V/G line, the peripheral electrode pad, and the inspection part (the inspection part is included in the V/G line in some cases);
a step (2) of inspecting operations of the semiconductor chip by bringing a probe into contact with at least the inspection part of the peripheral electrode pad and the inspection part; and
a step (3) of forming the rewiring line.

8. The method of manufacturing the semiconductor chip according to claim 7, wherein the step (2) inspects operations of the semiconductor chip by bringing a probe into contact with only the inspection part of the peripheral electrode pad and the inspection part.

9. A semiconductor package in which the semiconductor chip according to claim 1 is mounted onto a package substrate.

10. The semiconductor package according to claim 9, wherein the inspection part and the package substrate have a conductive connection.

11. The semiconductor package according to claim 9, wherein the inspection part and the package substrate do not have a conductive connection.
